(19) United States
(12) Patent Application Publication
(10) Pub. No.: US 2026/0173694 A1
(43) Pub. Date: Jun. 18, 2026

(54) Pixel Arrangement Structure, Display Panel and Display Device

(71) Applicants: Chengdu BOE Optoelectronics Technology Co., Ltd., Chengdu, Sichuan (CN); BOE Technology Group Co., Ltd., Beijing (CN)

(72) Inventors: Xinxing Guan, Beijing (CN); Yang Xiang, Beijing (CN); Kuo Shen, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/713,491

(22) PCT Filed: Aug. 30, 2023
(86) PCT No.: PCT/CN2023/115768

§ 371 Date: May 24, 2024

(51) Int. Cl. H10K 59/35

(52) U.S. Cl. CPC H10K 59/353; H10K 59/351

(57) ABSTRACT

At least one embodiment of the present disclosure provides a pixel arrangement structure, a display panel and a display device, the first display unit includes one first sub-pixel, one second sub-pixel and one third sub-pixel, the second display unit includes one first sub-pixel, two second sub-pixels and two third sub-pixels disposed around the one first sub-pixel, and the first display unit and the second display unit share a common first sub-pixel, the second sub-pixel in the first display unit is one of the two second sub-pixels in the second display unit, and the third sub-pixel in the first display unit is one of the two third sub-pixels in the second display unit; and the two second sub-pixels and the two third sub-pixels included in the second display unit in one of the pixel groups are respectively shared with four adjacent pixel groups.

### TECHNICAL FIELD

The present disclosure relates to a pixel arrangement structure, a display panel and a display device.

### BACKGROUND

Organic Light Emitting Diode (OLED) display device is an active light emitting display device, which is one of hot spots in a research field of flat panel display. Compared with the liquid crystal device, OLED display device has advantages of low energy consumption, low production cost, self-luminescence, wide viewing angle and fast response. At present, in the flat panel display fields, such as mobile phones, tablet computers and digital cameras, OLED display device has begun to replace traditional liquid crystal display (LCD).

OLED is formed by a glass substrate and a thin organic material film layer arranged on the glass substrate. In a case that electric current passes through, the organic material emits light, so that the OLED display panel can greatly save electric energy and can be made thinner.

### SUMMARY

At least one embodiment of the present disclosure provides a pixel arrangement structure, a display panel and a display device, a second display unit in a pixel group of the pixel arrangement structure includes two second sub-pixels and two third sub-pixels which are shared with four adjacent pixel groups respectively. Through borrowing the second sub-pixel and the third sub-pixel from adjacent pixel groups, the impact of central color separation bright spots on human eyes can be reduced. In a case that the display panel with the pixel arrangement structure is used in a vehicle-mounted system, the ambient light makes no impact on a driver's vision during the dark state display.

At least one embodiment of the present disclosure provides a pixel arrangement structure, and the pixel arrangement structure comprises a plurality of pixel groups arranged in an array, each of the pixel groups comprises a first display unit and a second display unit, both the first display unit and the second display unit comprise a first sub-pixel, a second sub-pixel, and a third sub-pixel that emit light of different colors; the first display unit comprises one first sub-pixel, one second sub-pixel and one third sub-pixel, the second display unit comprises one first sub-pixel, two second sub-pixels and two third sub-pixels disposed around the one first sub-pixel, and the first display unit and the second display unit share a common first sub-pixel, the second sub-pixel in the first display unit is one of the two second sub-pixels in the second display unit, and the third sub-pixel in the first display unit is one of the two third sub-pixels in the second display unit; and the two second sub-pixels and the two third sub-pixels comprised in the second display unit in one of the pixel groups are respectively shared with four adjacent pixel groups.

For example, in the pixel arrangement structure provided by at least one embodiment of the present disclosure, a triangle formed by connecting a geometric center of the first sub-pixel, a geometric center of the second sub-pixel and a geometric center of the third sub-pixel comprised in the first display unit is an acute triangle.

For example, in the pixel arrangement structure provided by at least one embodiment of the present disclosure, in the first display unit, a first pitch is between the first sub-pixel and the second sub-pixel, a second pitch is between the second sub-pixel and the third sub-pixel, and a third pitch is between the first sub-pixel and the third sub-pixel, the first pitch, the second pitch and the third pitch are all equal.

For example, in the pixel arrangement structure provided by at least one embodiment of the present disclosure, a quadrilateral formed by connecting the geometric centers of the two second sub-pixels and the geometric centers of the two third sub-pixels comprised in the second display unit is a parallelogram, and the geometric center of the first sub-pixel comprised in the second display unit coincides with an intersection point of two diagonals of the parallelogram.

For example, in the pixel arrangement structure provided by at least one embodiment of the present disclosure, in the second display unit, a fourth pitch is between the first sub-pixel and any one of the second sub-pixels, a fifth pitch is between the second sub-pixel and the third sub-pixel adjacent to it, and a sixth pitch is between the first sub-pixel and any one of the third sub-pixels, the fourth pitch, the fifth pitch and the sixth pitch are all equal.

For example, in the pixel arrangement structure provided by at least one embodiment of the present disclosure, the first sub-pixel is a blue sub-pixel, the second sub-pixel is one of a red sub-pixel and a green sub-pixel, and the third sub-pixel is the other of the red sub-pixel and the green sub-pixel.

For example, in the pixel arrangement structure provided by at least one embodiment of the present disclosure, a plurality of pixel groups are arranged in an array in a first direction and a second direction, the first direction intersects with the second direction, and is not perpendicular to the second direction, and geometric centers of a plurality of second display units are arranged in an array in the first direction and the second direction.

For example, in the pixel arrangement structure provided by at least one embodiment of the present disclosure, a planar shape of the first sub-pixel is a rectangle, and planar shapes of the second sub-pixels and the third sub-pixels are all parallelograms.

For example, in the pixel arrangement structure provided by at least one embodiment of the present disclosure, a planar shape of the first sub-pixel, a planar shape of the second sub-pixel and a planar shape of the third sub-pixel are all rectangles.

For example, in the pixel arrangement structure provided by at least one embodiment of the present disclosure, a planar shape of the first sub-pixel is a rhombus, a planar shape of the second sub-pixel and a planar shape of the third sub-pixel are both parallelograms, a maximum distance between opposite sides of the first sub-pixel is greater than a maximum distance between opposite sides of the second sub-pixel, the maximum distance between the opposite sides of the second sub-pixel is greater than a maximum distance between opposite sides of the third sub-pixel.

For example, in the pixel arrangement structure provided by at least one embodiment of the present disclosure, a planar shape of the first sub-pixel, a planar shape of the second sub-pixel and a planar shape of the third sub-pixel all comprise arc-shaped parts.

For example, in the pixel arrangement structure provided by at least one embodiment of the present disclosure, the planar shape of the first sub-pixel, the planar shape of the second sub-pixel and the planar shape of the third sub-pixel are all elliptical, a short diameter of an ellipse corresponding to the first sub-pixel is greater than a short diameter of an ellipse corresponding to the second sub-pixel and a short diameter of an ellipse corresponding to the third sub-pixel.

For example, in the pixel arrangement structure provided by at least one embodiment of the present disclosure, the planar shape of the first sub-pixel, the planar shape of the second sub-pixel and the planar shape of the third sub-pixel are all circular, and a diameter of a circle corresponding to the first sub-pixel is larger than a diameter of a circle corresponding to the second sub-pixel, a diameter of a circle corresponding to the second sub-pixel is larger than a diameter of a circle corresponding to the third sub-pixel.

For example, in the pixel arrangement structure provided by at least one embodiment of the present disclosure, a quadrilateral formed by connecting geometric centers of two second sub-pixels and geometric centers of two third sub-pixels comprised in the second display unit is a parallelogram, and a geometric center of a first sub-pixel comprised in the second display unit coincides with an intersection point of two diagonals of the parallelogram; in the second display unit, a fourth pitch is between the first sub-pixel and any one of the second sub-pixels, and a fifth pitch is between the second sub-pixel and the third sub-pixel adjacent to it, a sixth pitch is between the first sub-pixel and any one of the third sub-pixel, any two of the fourth pitch, the fifth pitch and the sixth pitch are not equal.

For example, in the pixel arrangement structure provided by at least one embodiment of the present disclosure, the first sub-pixel, the two second sub-pixels and the two third sub-pixels comprised in the second display unit are located in an irregular hexagon.

At least one embodiment of the present disclosure further provides a display panel, and the display panel comprises a display region and a non-display region, the display region is provided with a plurality of pixel openings with the pixel arrangement structure according to any one of the embodiments mentioned above.

At least one embodiment of the present disclosure further provides a display device, and the display device comprises any one of the display panel mentioned above and a driving circuit for providing a driving signal to the display panel.

### BRIEF DESCRIPTION OF DRAWINGS

In order to more clearly explain the technical solution of the embodiments of the present disclosure, the following will briefly introduce the drawings of the embodiments. Obviously, the drawings in the following description only relate to some embodiments of the present disclosure, but not limit the present disclosure.

FIG. 1 is a schematic planar structural diagram of a pixel arrangement structure provided by at least one embodiment of the present disclosure;

FIG. 2 is a schematic planar structural diagram of a first display unit provided by at least one embodiment of the present disclosure;

FIG. 3 is a schematic planar structural diagram of a second display unit provided by at least one embodiment of the present disclosure;

FIG. 4 is a schematic planar structural diagram of another first display unit provided by at least one embodiment of the present disclosure;

FIG. 5 shows a connection structure of geometric centers of a first sub-pixel, a second sub-pixel and a third sub-pixel included in the first display unit in FIG. 2;

FIG. 6 shows a connection structure of geometric centers of one first sub-pixel, two second sub-pixels and two third sub-pixels included in the second display unit in FIG. 3;

FIG. 7 is a schematic planar structural diagram of another second display unit provided by at least one embodiment of the present disclosure;

FIG. 8 is a schematic planar structural diagram of still another second display unit provided by at least one embodiment of the present disclosure;

FIG. 9 is a schematic planar structural diagram of still another second display unit provided by at least one embodiment of the present disclosure;

FIG. 10 is a schematic planar structural diagram of still another second display unit provided by at least one embodiment of the present disclosure;

FIG. 11 is a schematic structural diagram of an irregular hexagon provided by at least one embodiment of the present disclosure;

FIG. 12 is a schematic planar structural diagram of a display panel provided by at least one embodiment of the present disclosure; and

FIG. 13 is a block diagram of a display device provided by at least one embodiment of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms “comprise,” “comprising,” “comprise,” “comprising,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or a mechanical connection, but may comprise an electrical connection, directly or indirectly. “On,” “under,” “left,” “right” and the like are only used to indicate relative position relationship, and when the absolute position of the described object is changed, the relative position relationship may be changed accordingly.

Unless otherwise defined, the features such as “parallel”, “vertical” and “identical” used in the embodiments of the present invention all include cases such as “parallel”, “vertical” and “identical” in a strict sense, and cases such as “approximately parallel”, “approximately vertical” and “approximately identical” contain certain errors. For example, the above-mentioned “approximately” can indicate that the difference of the compared objects is within 10% or 5% of the average value of the compared objects. In a case that the number of a component or an element is not specified in the following of the embodiment of the present invention, it means that the component or the element can be one or more, or can be understood as at least one. “At least one” means one or more, and “multiple” means at least two. “Same layer arrangement” in the embodiment of the present invention refers to the relationship between multiple film layers formed by the same material after the same step (for example, one-step patterning process). The “same layer” here does not always mean that the thickness of multiple film layers is the same or the height of multiple film layers in a cross section is the same.

At present, in order to save production costs, most automobile manufacturers use liquid crystal display products for devices with display functions such as meters and central control equipment included in automobiles. Organic Light Emitting Diode (OLED) display device has many advantages, such as low energy consumption, low production cost, self-luminescence, wide viewing angle and fast response. Many automobile manufacturers have a strong interest in OLED products, and it has a good market prospect to use OLED display products in automobile instruments, central control equipment and co-pilot display screens.

Compared to a traditional combination structure of a liquid crystal display device (LCD) and a liquid crystal display device lifting part (LCF), the design of replacing liquid crystal display device with vehicle-mounted products based on OLED display device can solve the problems of moire and insufficient display brightness upon displaying images, but there are still following problems to be improved in a case of using OLED as a vehicle-mounted display device: considering the particularity of the vehicle-mounted products, the pixel structure adopts a real RGB ternary pixel design, and the pixel design will greatly affect the dark display effect, so that there is an urgent requirement for a pixel arrangement structure design to solve the above problems of OLED devices in the vehicle-mounted products. In addition, with the rapid development of display technology, consumers have higher and higher requirements for the resolution of the display screen. At present, the pixel arrangement method with high resolution is sub-pixel rendering (SPR) method. For example, adjacent pixel units will share at least one of the red sub-pixel R and the blue sub-pixel B.

The inventors of the present disclosure have noticed that a pixel arrangement structure can be designed, a second display unit in a pixel group of the pixel arrangement structure includes two second sub-pixels and two third sub-pixels respectively share with four adjacent pixel groups. Through borrowing the second sub-pixel and the third sub-pixel from adjacent pixel groups, the impact of central color separation bright spots on human eyes can be reduced, and in a case that the display panel with the pixel arrangement structure is used in a vehicle-mounted system, the ambient light makes no impact on a driver's vision during the dark state display, thus improving the safety upon driving.

At least one embodiment of the present disclosure provides a pixel arrangement structure, the pixel arrangement structure includes: a plurality of pixel groups arranged in an array, each of the pixel groups includes a first display unit and a second display unit, both the first display unit and the second display unit include a first sub-pixel, a second sub-pixel, and a third sub-pixel that emit light of different colors. The first display unit includes one first sub-pixel, one second sub-pixel and one third sub-pixel. The second display unit includes one first sub-pixel, two second sub-pixels and two third sub-pixels disposed around the one first sub-pixel, and the first display unit and the second display unit share a common first sub-pixel, the second sub-pixel in the first display unit is one of the two second sub-pixels in the second display unit, and the third sub-pixel in the first display unit is one of the two third sub-pixels in the second display unit. The two second sub-pixels and the two third sub-pixels included in the second display unit in one of the pixel groups are respectively shared with four adjacent pixel groups. The pixel arrangement structure makes that the pixel group includes a total of five sub-pixels, each of the pixel groups includes a first display unit and a second display unit, the three sub-pixels of three colors included in the first display unit are shared with three of the five sub-pixels included in the second display unit, thereby reducing the number of the sub-pixels, and the first image display or the second image display can be performed under the drive of different driving circuits. Therefore, the sub-pixels in a pixel group can achieve high-resolution display effect from low-resolution physical resolution through the principle of borrowing color, thus solving the technical problem of limited pixel resolution. Moreover, the two second sub-pixels and the two third sub-pixels included in the second display unit in a pixel group are shared with the four adjacent pixel groups respectively, thereby further reducing the number of sub-pixels, making the structure of each of the pixel groups simple, and thereby simplifying the structural design of the entire display panel.

For example, in a case that the pixel arrangement structure is used in a display region of a display product in the vehicle-mounted field, the impact of the central color separation bright spot on human eyes can be reduced through borrowing the sub-pixels, and the ambient light makes no impact on a driver's vision during the dark state display.

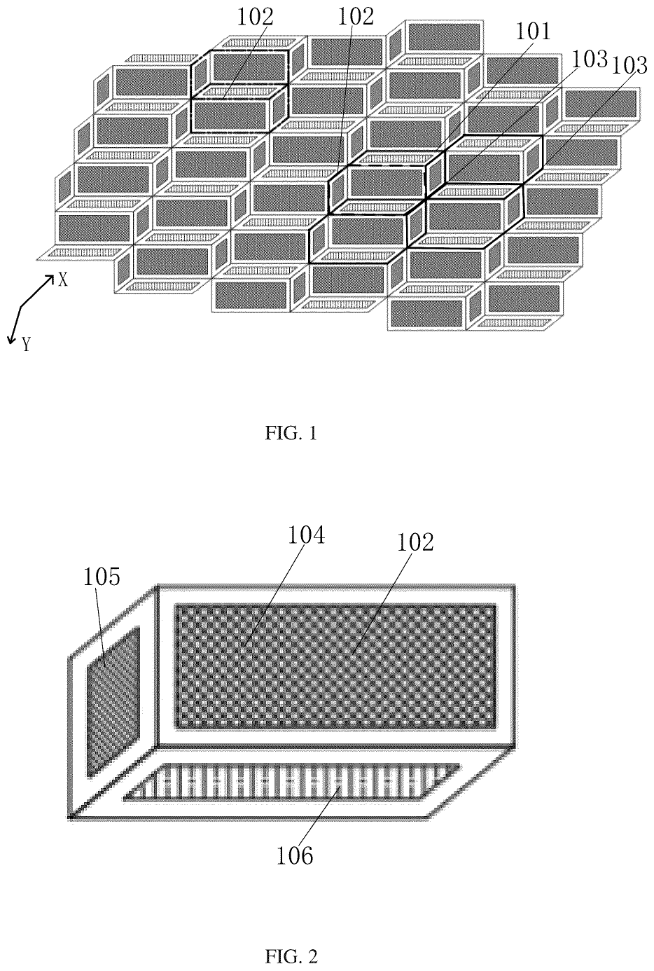

For example, FIG. 1 is a schematic planar structural diagram of a pixel arrangement structure provided by at least one embodiment of the present disclosure, as shown in FIG. 1, the pixel arrangement structure 100 includes: a plurality of pixel groups 101 arranged in an array, each of the pixel groups 101 includes a first display unit 102 and a second display unit 103. That is, each of the pixel groups 101 is a repeating unit, and a plurality of repeating units are arranged in an array in a first direction X and a second direction Y that intersect with each other, as shown in FIG. 1, the first direction X intersects with the second direction Y, and is not perpendicular to each other, and an angle between the first direction X and the second direction Y is an obtuse angle.

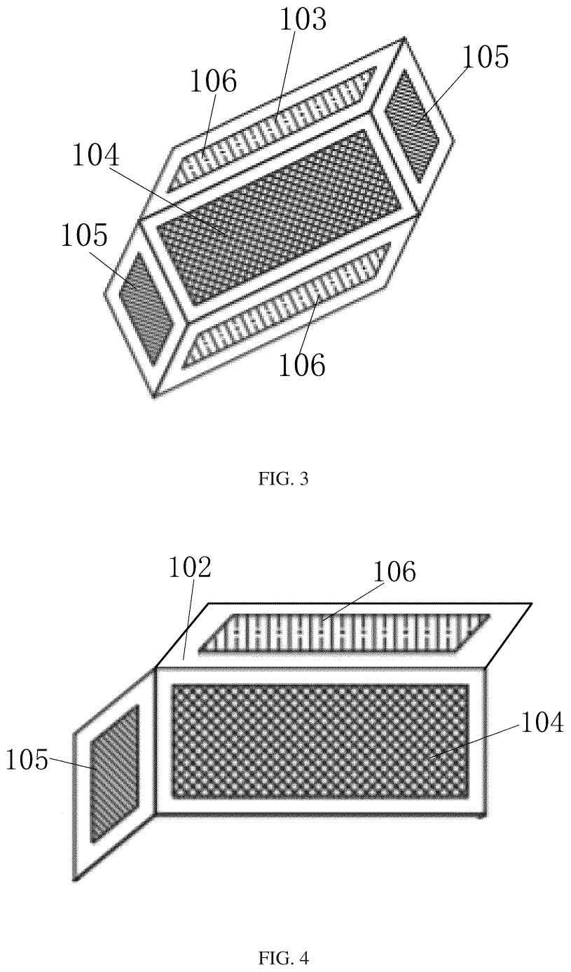

For example, FIG. 2 is a schematic planar structural diagram of a first display unit provided by at least one embodiment of the present disclosure, FIG. 3 is a schematic planar structural diagram of at least one second display unit provided by an embodiment of the present disclosure, as shown in FIG. 2 and FIG. 3, the first display unit 102 and the second display unit 103 both include a first sub-pixel 104, a second sub-pixel 105 and a third sub-pixel 106 that emit light of different colors, only the number of the sub-pixels and the arrangement manner of the sub-pixels in the first display unit 102 and the second display unit 103 are different. The first display unit 102 includes one first sub-pixel 104, one second sub-pixel 105 and one third sub-pixel 106. The second display unit 103 includes one first sub-pixel 104 and two second sub-pixels 105 and two third sub-pixels 106 disposed around the one first sub-pixel 104, and the first display unit 102 and the second display unit 103 share a common first sub-pixel 104, a second sub-pixel 105 in the first display unit 102 is one of the two second sub-pixels 105 in the second display unit 103, and a third sub-pixel 106 in the first display unit 102 is one of the two third sub-pixels 106 in the second display unit 103, that is each of the pixel groups 101 includes five sub-pixels, and the second display unit 103 includes five sub-pixels in one pixel group 101, the first display unit 102 located in the same pixel group 101 as the second display unit 103 includes three sub-pixels in one pixel group 101, and the two second sub-pixels 105 and two third sub-pixels 106 included in the second display unit 103 in a pixel group 101 are respectively shared with the four adjacent pixel groups 101.

For example, in one embodiment, the first sub-pixel 104, the second sub-pixel 105, and the third sub-pixel 106 may respectively be a blue sub-pixel B, a green sub-pixel G, and a red sub-pixel R, that is, the first display unit 102 includes one blue sub-pixel B, one green sub-pixel G, and one red sub-pixel R, and the second display unit 103 includes one blue sub-pixel B, two green sub-pixels G and two red sub-pixels R disposed around the one blue sub-pixel B. Of course, the embodiment of the present disclosure is not limited thereto, the first sub-pixel 104, the second sub-pixel 105 and the third sub-pixel 106 may respectively be a green sub-pixel G, a blue sub-pixel B and a red sub-pixel R, that is, the first display unit 102 includes a green sub-pixel G, a blue sub-pixel B and a red sub-pixel R, and the second display unit 103 includes one green sub-pixel G, two blue sub-pixels B and two red sub-pixels R disposed around the one green sub-pixel G. It is also possible that the first sub-pixel 104, the second sub-pixel 105 and the third sub-pixel 106 are a red sub-pixel R, a green sub-pixel G and a blue sub-pixel B, respectively, that is, the first display unit 102 includes the red sub-pixel R, the green sub-pixel G, and the blue sub-pixel B, and the second display unit 103 includes one red sub-pixel R, two blue sub-pixels B and two green sub-pixels G disposed around the one red sub-pixel R.

For example, as shown in FIG. 2 and FIG. 3, an area of each first sub-pixel 104 is larger than that of each second sub-pixel 105 and larger than that of each third sub-pixel 106. Because the blue sub-pixel B has the lowest luminous brightness, in order to ensure the uniformity of white light displayed by the final display panel, it is usually necessary to define the first sub-pixel 104 with the largest area as the blue sub-pixel, and one of the second sub-pixel 105 and the third sub-pixel 106 with smaller areas as the red sub-pixel R and the green sub-pixel G respectively.

For example, as shown in FIG. 2, the first display unit 102 is shown in a plane formed by a horizontal direction and a direction perpendicular to the horizontal plane. The third sub-pixel 106 is disposed on the horizontal plane, the plane of the first sub-pixel 104 is perpendicular to the horizontal plane, and the plane of the second sub-pixel 105 is perpendicular to the horizontal plane. The first sub-pixel 104, the second sub-pixel 105 and the third sub-pixel 106 included in the first display unit 102 form a structure of a half of a cuboid. The plane in which the first sub-pixel 104 is located, the plane in which the second sub-pixel 105 is located and the plane in which the third sub-pixel 106 is located intersect at a point, the plane in which the first sub-pixel 104 is located and the plane in which the second sub-pixel 105 is located share a common edge, the plane in which the second sub-pixel 105 is located and the plane in which the third sub-pixel 106 is located share a common edge, and the plane in which the first sub-pixel 104 is located and the plane in which the third sub-pixel 106 is located also share a common edge, but embodiments of the present disclosure are not limited thereto.

It should be noted that, although in FIG. 1, FIG. 2, and FIG. 3, there are boxes around the first sub-pixel 104, the second sub-pixel 105 and the third sub-pixel 106, but in fact these boxes are all virtual boxes in order to show the relationship among the sub-pixels more clearly. For example, an edge shared by the plane in which the first sub-pixel 104 is located and the plane in which the second sub-pixel 105 is located is an edge shared by the box surrounding the first sub-pixel 104 and the box surrounding the second sub-pixel 105. The edge shared by the plane in which the second sub-pixel 105 is located and the plane in which the third sub-pixel 106 is located is one edge shared by the box enclosing the second sub-pixel 105 and the box enclosing the third sub-pixel 106. The edge shared by the plane in which the first sub-pixel 104 is located and the plane in which the third sub-pixel 106 is located is the one edge shared by the box enclosing the first sub-pixel 104 and the box enclosing the third sub-pixel 106.

For example, in a case that the pixel driving circuit drives the first display unit 102 to display, a first sub-pixel 104, a second sub-pixel 105 and a third sub-pixel 106 form a pixel point, and display the conventional three primary colors of R, G and B.

For example, the second display unit 103 uses pentile display, the pentile display is a way to reduce the number of sub-pixels by sharing sub-pixels with adjacent pixels, so as to achieve the effect of simulating high resolution with low resolution, and further achieve the effect of higher visual perception brightness for viewers under the same brightness. In addition, this pixel arrangement structure also makes the cost of manufacturing a display panel lower. While the pixel driving circuit drives the second display unit 103 to display, one pixel displayed by the pentile will “borrow” another color of its adjacent pixel to form three primary colors. Pentile arrangement appeared with the birth of OLED display materials. For OLED display devices that emit light actively, RGB of OLED corresponds to organic materials that emit red light, organic materials that emit green light and organic materials that emit blue light respectively. At present, the display requires high resolution and requires small and high-density integration of each luminescent material with great technological difficulty and high manufacturing cost. Using pentile arrangement and borrowing sub-pixel for adjacent display units can make the area of the light-emitting layer of each sub-pixel larger, thus reducing the technological difficulty in the preparation process, and the production cost is also reduced. Moreover, pentile displays a higher pixel density, so it can better display high-resolution images and colorful images, and can also clearly display pictures under direct sunlight exposure.

For example, FIG. 4 is a schematic planar structural diagram of another first display unit provided by at least one embodiment of the present disclosure. As shown in FIG. 4, the first display unit 102 is shown in a plane formed by a horizontal direction and a direction perpendicular to the horizontal plane. The third sub-pixel 106 is located on a horizontal plane, and the plane in which the first sub-pixel 104 is located is perpendicular to the horizontal plane, and the plane in which the second sub-pixel 105 is located is perpendicular to the horizontal plane. The plane where the first sub-pixel 104 is located, the plane where the second sub-pixel 105 is located and the plane where the third sub-pixel 106 is located intersect at a point. The plane where the first sub-pixel 104 is located and the plane where the second sub-pixel 105 is located share an edge, and the plane where the first sub-pixel 104 is located and the plane where the third sub-pixel 106 is located share an edge. However, the plane where the second sub-pixel 105 is located and the plane where the third sub-pixel 106 is located do not share an edge, which are not limited in the embodiments of the present disclosure.

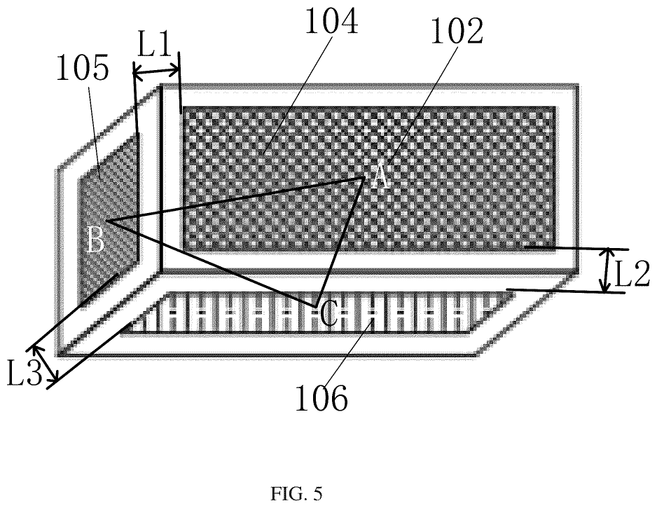

For example, FIG. 5 shows a connection structure of geometric centers of a first sub-pixel, a second sub-pixel and a third sub-pixel included in the first display unit in FIG. 2. As shown in FIG. 5, a triangle ABC formed by connecting a geometric center A of a first sub-pixel 104, a geometric center B of a second sub-pixel 105 and a geometric center C of a third sub-pixel 106 included in the first display unit 102 is an acute triangle. For example, <ABC, <ACB and <BAC in the acute triangle are all acute angles, that is, they are all less than 90°. With this arrangement, the structure of the first display unit 102 can be made more compact, and the display screen of the finally formed first display unit 102 can be more uniform.

For example, as shown in FIG. 5, in a first display unit 102, a first pitch L1 is between a first sub-pixel 104 and a second sub-pixel 105, a second pitch L2 is between a second sub-pixel 105 and a third sub-pixel 106, a third pitch L3 is between the first sub-pixel 104 and the third sub-pixel 106, the first pitch L1, the second pitch L2 and the third pitch L3 are all equal. In this way, the distances between any two of the first sub-pixel 104, the second sub-pixel 105 and the third sub-pixel 106 can be made equal, and the uniformity of the display screen can be further ensured as the first display unit 102 displays.

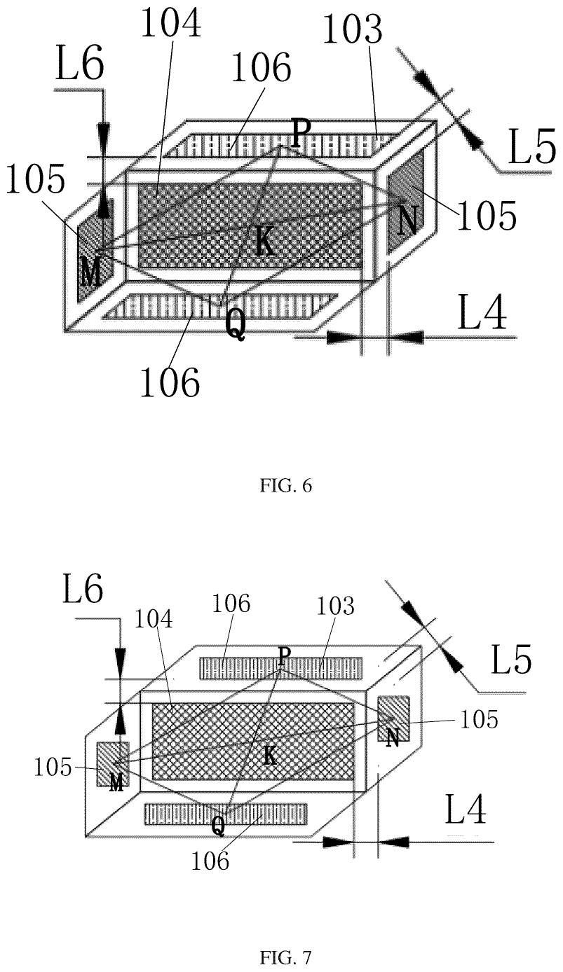

For example, FIG. 6 shows a connection structure of geometric centers of one first sub-pixel, two second sub-pixels and two third sub-pixels included in the second display unit in FIG. 3. As shown in FIG. 6, a quadrilateral formed by connecting the geometric centers M and N of two second sub-pixels 105 and the geometric centers P and Q of two third sub-pixels 106 included in the second display unit 103 is a parallelogram MNPQ. Moreover, the geometric center K of a first sub-pixel 104 included in the second display unit 103 coincides with the intersection point of two diagonals MN and PQ of the parallelogram MNPQ. This structural design makes the structure of a first sub-pixel, two second sub-pixels and two third sub-pixels included in the second sub-pixel 105 more compact, thus making the display picture of the finally formed second display unit 103 more uniform, and enabling the pixel arrangement structure to adopt as few sub-pixels as possible to realize two different display modes.

For example, as shown in FIG. 6, in the second display unit 103, a fourth pitch L4 is between the first sub-pixel 104 and any one of the second sub-pixels 105, a fifth pitch L5 is between the second sub-pixel 105 and the third sub-pixel 106 adjacent to it, and a sixth pitch L6 is between the first sub-pixel 104 and any one of the third sub-pixels 106. The fourth pitch LA, the fifth pitch L5 and the sixth pitch L6 are all equal. This design can make the picture displayed by the second display unit 103 more uniform upon performing image display.

For example, in an example, in one pixel group 101, the second display unit 103 includes two second sub-pixels 105 with the same area and the same shape, and the two second sub-pixels 105 are oppositely arranged on two sides of the first sub-pixel 104, for example, one of the two second sub-pixels 105 is on the left side of the first sub-pixel 104 and the other is on the right side of the first sub-pixel 104. A minimum distance between the second sub-pixel 105 located on the left side of the first sub-pixel 104 and the first sub-pixel 104 is equal to a minimum distance between the second sub-pixel 105 located on the right side of the first sub-pixel 104 and the first sub-pixel 104. The two third sub-pixels 106 have the same area and shape, and they are oppositely arranged on two sides of the first sub-pixel 104. For example, one of the two third sub-pixels 106 is on the upper side of the first sub-pixel and the other is on the lower side of the first sub-pixel. A minimum distance between the third sub-pixel 106 located on the upper side of the first sub-pixel 104 and the first sub-pixel 104 is equal to a minimum distance between the third sub-pixel 106 located at the lower side of the first sub-pixel 104 and the first sub-pixel 104.

For example, in the structure shown in FIG. 6, the first sub-pixel 104 is a blue sub-pixel B, the second sub-pixel 105 is one of the red sub-pixel R and the green sub-pixel B, and the third sub-pixel 106 is the other one of the red sub-pixel R and the green sub-pixel G. For example, the first sub-pixel 104 is the blue sub-pixel B, the second sub-pixel 105 is the red sub-pixel R, and the third sub-pixel 106 is the green sub-pixel G. In the pixel group shown in FIG. 6, the second sub-pixel 105 on the left side of the first sub-pixel 104 is shared with the adjacent pixel group on the left side of the pixel group, and in the pixel group shown in FIG. 6, the second sub-pixel 105 on the right side of the first sub-pixel 104 in the pixel group shown in FIG. 6 is shared with the adjacent pixel group on the right side of the pixel group. In the pixel group shown in FIG. 6, the third sub-pixel 106 located on the upper side of the first sub-pixel 104 is shared with the adjacent pixel group located on the upper side of the pixel group, and the third sub-pixel 105 located at the lower side of the first sub-pixel 104 in the pixel group shown in FIG. 6 is shared with the adjacent pixel group located at the lower side of the pixel group.

For example, with reference to FIG. 1 and FIG. 6, a plurality of pixel groups 101 are arranged in an array in the first direction X and the second direction Y. The first direction X intersects with the second direction Y, and is not perpendicular to the second direction Y, and the geometric centers K of the plurality of second display units 103 are arranged in an array in the first direction X and the second direction Y.

For example, in the structure shown in FIG. 6, a planar shape of the first sub-pixel 104 is a rectangle, and the planar shapes of the two second sub-pixels 105 and the two third sub-pixels 106 are all parallelograms. An area of the first sub-pixel 104 is larger than an area of any one of the second sub-pixels 105, and an area of the first sub-pixel 104 is larger than an area of any one of the third sub-pixels 106. The shape of the arrangement structure of the 5 sub-pixels that form the second display unit is an irregular hexagon.

For example, FIG. 7 is a schematic planar structural diagram of another second display unit provided by at least one embodiment of the present disclosure. As shown in FIG. 7, the planar shape of the first sub-pixel 104, the planar shape of the second sub-pixel 105 and the planar shape of the third sub-pixel 106 are all rectangular, and the second display unit 103 includes two second sub-pixels 105 with equal areas and the same shape, and the two second sub-pixels 105 are oppositely arranged on two sides of the first sub-pixel 104. For example, one of the two second sub-pixels 105 is on the left side of the first sub-pixel 104 and the other one is on the right side of the first sub-pixel, and a minimum distance between the second sub-pixel 105 on the left side and the first sub-pixel 104 is equal to a minimum distance between the second sub-pixel 105 on the right side and the first sub-pixel 104. Two third sub-pixels 106 have the same area and the same shape, and are oppositely arranged on two sides of the first sub-pixel 104. For example, one of the two third sub-pixels 106 is on the upper side of the first sub-pixel 104 and the other one is on the lower side of the first sub-pixel, and a minimum distance between the third sub-pixel 106 on the upper side and the first sub-pixel 104 is equal to that between the third sub-pixel 106 on the lower side and the first sub-pixel 104. A length of a long side of the first sub-pixel 104 is greater than that of the third sub-pixel 106, and a length of a long side of the third sub-pixel 106 is greater than that of the second sub-pixel 105. A length of a short side of the first sub-pixel 104 is greater than that of the second sub-pixel 105, and a length of a short side of the second sub-pixel 105 is greater than that of the third sub-pixel 106. It can be seen from FIG. 7, an area of the first sub-pixel 104 is larger than an area of each of the third sub-pixels 106, and an area of each of the third sub-pixels 106 is larger than an area of each of the second sub-pixels 105. And in FIG. 7, a fourth pitch L4 is between the first sub-pixel 104 and any one of the second sub-pixels 105, a fifth pitch L5 is between the second sub-pixel 105 and the third sub-pixel 106 adjacent to it, and a sixth pitch L6 is between the first sub-pixel 104 and any one of the third sub-pixels 106. The fourth pitch L4, the fifth pitch L5 and the sixth pitch L6 are all equal. This design can make the picture displayed by the second display unit 103 more uniform upon performing display.

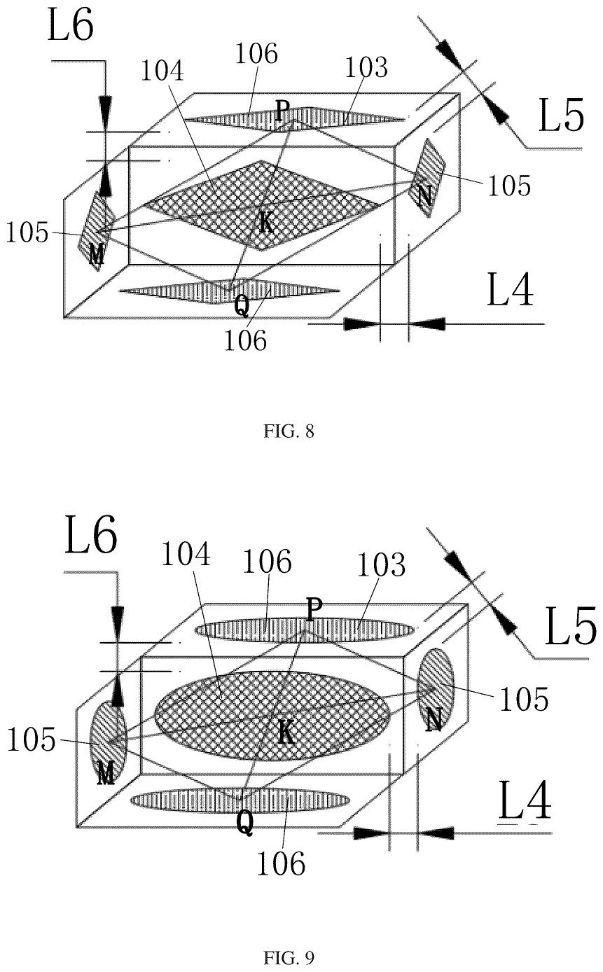

For example, FIG. 8 is a schematic planar structural diagram of still another second display unit provided by at least one embodiment of the present disclosure. As shown in FIG. 8, the planar shape of the first sub-pixel 104 is a rhombus, the planar shape of the second sub-pixel 105 and the planar shape of the third sub-pixel 106 are both parallelograms. A maximum distance between the opposite sides of the first sub-pixel 104 is greater than a maximum distance between the opposite sides of the second sub-pixel 105. A maximum distance between the opposite sides of the second sub-pixel 105 is greater than a maximum distance between the opposite sides of the third sub-pixel 106. It can be seen from FIG. 8, an area of the first sub-pixel 104 is larger than an area of each of the third sub-pixels 106, and the area of each of the third sub-pixels 106 is larger than an area of each of the second sub-pixels 105. And in FIG. 8, a fourth pitch LA is between the first sub-pixel 104 and any one of the second sub-pixels 105, a fifth pitch L5 is between the second sub-pixel 105 and the third sub-pixel 106 adjacent to it, and a sixth pitch L6 is between the first sub-pixel 104 and any one of the third sub-pixels 106. The fourth pitch L4, the fifth pitch L5 and the sixth pitch L6 are all equal. This design can make the picture displayed by the second display unit 103 more uniform upon performing display.

For example, in the pixel arrangement structure provided by at least one embodiment of the present disclosure, the planar shape of the first sub-pixel 104, the planar shape of the second sub-pixel 105 and the planar shape of the third sub-pixel 106 may all include arc-shaped parts, the arc-shaped parts make the edge of the pixel opening smoother, thereby reducing the sawtooth sense of the display screen.

For example, FIG. 9 is a schematic planar structural diagram of still another second display unit provided by at least one embodiment of the present disclosure. As shown in FIG. 9, the planar shape of the first sub-pixel 104, the planar shape of the two second sub-pixels 105 and the planar shape of the two third sub-pixels 106 are all elliptical. A short diameter of an ellipse corresponding to the first sub-pixel 104 is greater than a short diameter of an ellipse corresponding to the second sub-pixel 105 and a short diameter of an ellipse corresponding to the third sub-pixel 106, and the short diameter of the ellipse corresponding to the second sub-pixel 105 is greater than or equal to the short diameter of the ellipse corresponding to the third sub-pixel 106. A long diameter of the ellipse corresponding to the first sub-pixel 104 is greater than or equal to a long diameter of the ellipse corresponding to the third sub-pixel 106, the long diameter of the ellipse corresponding to the third sub-pixel 106 is greater than a long diameter of the ellipse corresponding to the second sub-pixel 105. Setting the planar shapes of the first sub-pixel 104, the two second sub-pixels 105 and the two third sub-pixels 106 to be elliptical can make the edges of each of the pixel openings smoother, thus reducing the sawtooth sense of the display screen. It can be seen from FIG. 9, the area of the first sub-pixel 104 is larger than the area of each of the third sub-pixels 106, and the area of each of the third sub-pixels 106 is larger than an area of each of the second sub-pixels 105. In FIG. 9, a fourth pitch LA is between the first sub-pixel 104 and any one of the second sub-pixels 105, a fifth pitch L5 is between the second sub-pixel 105 and the third sub-pixel 106 adjacent to it, and a sixth pitch L6 is between the first sub-pixel 104 and any one of the third sub-pixels 106. The fourth pitch LA, the fifth pitch L5 and the sixth pitch L6 are all equal. This design can make the picture displayed by the second display unit 103 more uniform upon performing display.

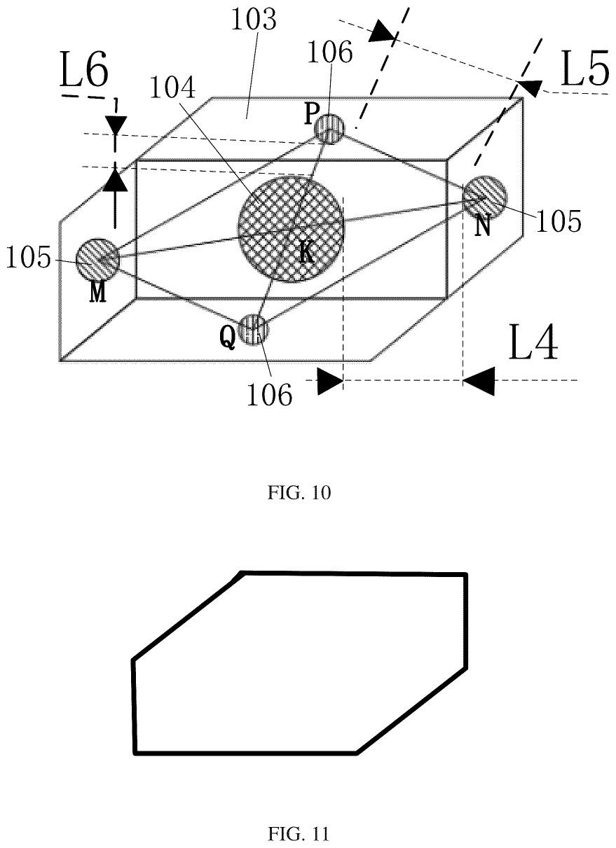

For example, FIG. 10 is a schematic planar structural diagram of still another second display unit provided by at least one embodiment of the present disclosure. As shown in FIG. 10, the planar shapes of a first sub-pixel 104, two second sub-pixels 105 and two third sub-pixels 106 are all circular, and a diameter of a circle corresponding to the first sub-pixel 104 is larger than a diameter of a circle corresponding to the second sub-pixel 105. The diameter of the circle corresponding to the second sub-pixel 105 is larger than a diameter of a circle corresponding to the third sub-pixel 106, that is, the area of the first sub-pixel 104 is larger than the area of the second sub-pixel 105, and the area of the second sub-pixel 105 is larger than the area of the third sub-pixel 106. As shown in FIG. 10, a fourth pitch LA is between the first sub-pixel 104 and any one of the second sub-pixels 105, and a fifth pitch L5 is between the second sub-pixel 105 and the third sub-pixel 106 adjacent to it. Any two of the fourth pitch LA, the fifth pitch L5 and the sixth pitch L6 are not equal.

For example, in the embodiment shown in FIG. 10, a sixth pitch L6 is between the first sub-pixel 104 and any one of the third sub-pixels 106, the fifth pitch L5 is greater than the fourth pitch LA, and the fourth pitch LA is greater than the sixth pitch L6.

Of course, the embodiment of the present disclosure is not limited to this, and in the structure shown in FIG. 10, any two of the fourth pitch LA, the fifth pitch L5 and the sixth pitch L6 may be equal.

It should be noted that, in the embodiment of the present disclosure, the embodiment in which the planar shapes of the first sub-pixel 104, the second sub-pixel 105 and the third sub-pixel 106 all include arc-shaped parts is not limited to the embodiments shown in FIG. 9 and FIG. 10 above, as long as the planar shapes of the first sub-pixel 104, the second sub-pixel 105 and the third sub-pixel 106 all include arc-shaped parts, for example, the planar shapes of the first sub-pixel 104, the second sub-pixel 105 and the third sub-pixel 106 may all include fan-shaped parts, arcuate parts or semi-circular parts and so on.

For example, in the embodiment shown in FIG. 6 to FIG. 10, a quadrilateral formed by connecting the geometric centers M and N of two second sub-pixels 105 and the geometric centers P and Q of two third sub-pixels 106 included in the second display unit 103 is a parallelogram MNPQ, and the geometric center K of a first sub-pixel 104 included in the second display unit 103 coincides with the intersection point of two diagonals MN and PQ of the parallelogram MNPQ.

For example, in the embodiment shown in FIG. 6 to FIG. 10, one first sub-pixel 104, two second sub-pixels 105 and two third sub-pixels 106 included in the second display unit 103 are located in an irregular hexagon. For example, FIG. 11 is a schematic structural diagram of an irregular hexagon provided by at least one embodiment of the present disclosure. As shown in FIG. 11, the irregular hexagon has two adjacent sides perpendicular to each other. For example, setting the outer contour of each of the pixel groups as an irregular hexagon can make the whole structure of the pixel group uniform, and at the same time, it can be distributed more evenly based on the three primary colors of red, green and blue to make the display effect stable.

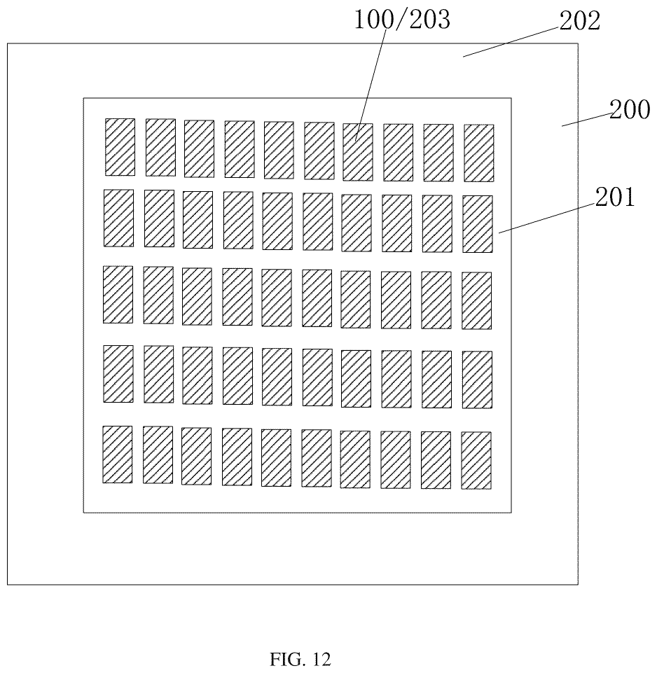

At least one embodiment of the present disclosure further provides a display panel. FIG. 12 is a schematic planar structural diagram of a display panel provided by at least one embodiment of the present disclosure. As shown in FIG. 12, the display panel 200 includes a display region 201 and a non-display region 202. The display region 201 is provided with a plurality of pixel openings 203 with the pixel arrangement structure 100 as in any one of the above embodiments, and peripheral wiring is provided in the non-display region 202. Through sharing the sub-pixels in one pixel group and the sub-pixels in the adjacent pixel group, the display panel 200 can have high resolution and high display PPI, and in a case that the pixel group with the pixel arrangement structure is applied to the display panel, the edge display of the display panel is uniform, and the sawtooth sense is weak, and it can also be displayed by the first display unit and the second display unit respectively upon being driven by different driving circuits.

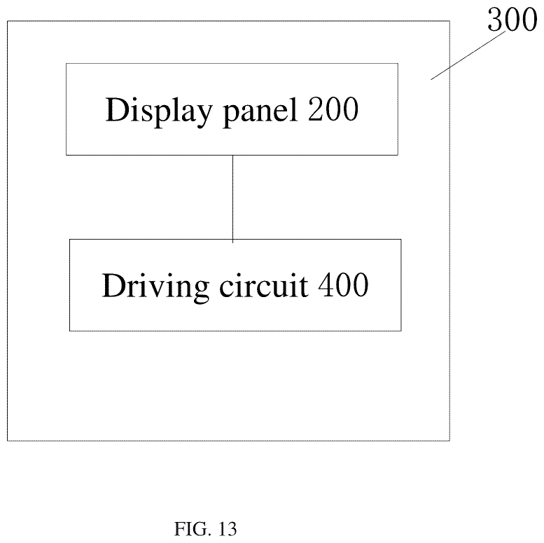

At least one embodiment of the present disclosure further provides a display device. For example, FIG. 13 is a block diagram of a display device provided by at least one embodiment of the present disclosure. As shown in FIG. 13, the display device 300 includes the display panel 200 in any one of the above embodiments and a driving circuit 400 for providing driving signals to the display panel 200. The display device can be any product or component with display function, such as a mobile phone, a tablet computer, a television, a display, a notebook computer and a digital photo frame.

The pixel arrangement structure, the display panel and the display device provided by at least one embodiment of the present disclosure have at least one of the following beneficial technical effects:
(1) The pixel arrangement structure is provided by at least one embodiment of the present disclosure, and a second display unit in a pixel group of the pixel arrangement structure includes two second sub-pixels and two third sub-pixels which are respectively shared with four adjacent pixel groups respectively. Through borrowing the second sub-pixel and the third sub-pixel from adjacent pixel groups, the impact of central color separation bright spots on human eyes can be reduced. In a case that the display panel with the pixel arrangement structure is used in a vehicle-mounted system, the ambient light makes no impact on a driver's vision during the dark state display.
(2) In the pixel arrangement structure provided by at least one embodiment of the present disclosure, the three sub-pixels of three colors included in the first display unit are shared with three of the five sub-pixels included in the second display unit, thereby reducing the number of sub-pixels, and the first image display or the second image display can be performed under the drive of different driving circuits. Therefore, the sub-pixels in a pixel group can achieve high-resolution display effect from low-resolution physical resolution through the principle of borrowing color, thus solving the technical problem of limited pixel resolution.

The following statements should be noted:
(1) The drawings accompanying the embodiment(s) of the present disclosure involve only the structure(s) in connection with the embodiment(s) of the present disclosure, and other structure(s) can be referred to common design(s).
(2) For the sake of clarity, in the drawings used to describe the embodiments of the present disclosure, the thickness of layers or regions is enlarged or reduced, that is, these drawings are not drawn to actual scale.
(3) In case of no conflict, features in an embodiment or in different embodiments of the present disclosure can be combined with each other to obtain a new embodiment.

The above are merely specific implementations of the present disclosure without limiting the protection scope of the present disclosure thereto, the protection scope of the present disclosure should be based on the protection scope of the appended claims.

1. A pixel arrangement structure, comprising a plurality of pixel groups arranged in an array, wherein each of the pixel groups comprises a first display unit and a second display unit, both the first display unit and the second display unit comprise a first sub-pixel, a second sub-pixel, and a third sub-pixel that emit light of different colors;
the first display unit comprises one first sub-pixel, one second sub-pixel and one third sub-pixel, the second display unit comprises one first sub-pixel, two second sub-pixels and two third sub-pixels disposed around the one first sub-pixel, and the first display unit and the second display unit share a common first sub-pixel, the second sub-pixel in the first display unit is one of the two second sub-pixels in the second display unit, and the third sub-pixel in the first display unit is one of the two third sub-pixels in the second display unit; and
the two second sub-pixels and the two third sub-pixels comprised in the second display unit in one of the pixel groups are respectively shared with four adjacent pixel groups.

2. The pixel arrangement structure according to claim 1, wherein a triangle formed by connecting a geometric center of the first sub-pixel, a geometric center of the second sub-pixel and a geometric center of the third sub-pixel comprised in the first display unit is an acute triangle.

3. The pixel arrangement structure according to claim 2, wherein in the first display unit, a first pitch is between the first sub-pixel and the second sub-pixel, a second pitch is between the second sub-pixel and the third sub-pixel, and a third pitch is between the first sub-pixel and the third sub-pixel, the first pitch, the second pitch and the third pitch are all equal.

4. The pixel arrangement structure according to claim 2, wherein a quadrilateral formed by connecting the geometric centers of the two second sub-pixels and the geometric centers of the two third sub-pixels comprised in the second display unit is a parallelogram, and the geometric center of the first sub-pixel comprised in the second display unit coincides with an intersection point of two diagonals of the parallelogram.

5. The pixel arrangement structure according to claim 4, wherein in the second display unit, a fourth pitch is between the first sub-pixel and any one of the second sub-pixels, a fifth pitch is between the second sub-pixel and the third sub-pixel adjacent to it, and a sixth pitch is between the first sub-pixel and any one of the third sub-pixels, the fourth pitch, the fifth pitch and the sixth pitch are all equal.

6. The pixel arrangement structure according to claim 1, wherein the first sub-pixel is a blue sub-pixel, the second sub-pixel is one of a red sub-pixel and a green sub-pixel, and the third sub-pixel is the other of the red sub-pixel and the green sub-pixel.

7. The pixel arrangement structure according to claim 1, wherein a plurality of pixel groups are arranged in an array in a first direction and a second direction, the first direction intersects with the second direction, and is not perpendicular to the second direction, and geometric centers of a plurality of second display units are arranged in an array in the first direction and the second direction.

8. The pixel arrangement structure according to claim 1, wherein a planar shape of the first sub-pixel is a rectangle, and planar shapes of the second sub-pixels and the third sub-pixels are all parallelograms.

9. The pixel arrangement structure according to claim 1, wherein a planar shape of the first sub-pixel, a planar shape of the second sub-pixel and a planar shape of the third sub-pixel are all rectangles.

10. The pixel arrangement structure according to claim 1, wherein a planar shape of the first sub-pixel is a rhombus, a planar shape of the second sub-pixel and a planar shape of the third sub-pixel are both parallelograms, a maximum distance between opposite sides of the first sub-pixel is greater than a maximum distance between opposite sides of the second sub-pixel, the maximum distance between the opposite sides of the second sub-pixel is greater than a maximum distance between opposite sides of the third sub-pixel.

11. The pixel arrangement structure according to claim 1, wherein a planar shape of the first sub-pixel, a planar shape of the second sub-pixel and a planar shape of the third sub-pixel all comprise arc-shaped parts.

12. The pixel arrangement structure according to claim 11, wherein the planar shape of the first sub-pixel, the planar shape of the second sub-pixel and the planar shape of the third sub-pixel are all elliptical, a short diameter of an ellipse corresponding to the first sub-pixel is greater than a short diameter of an ellipse corresponding to the second sub-pixel and a short diameter of an ellipse corresponding to the third sub-pixel.

13. The pixel arrangement structure according to claim 11, wherein the planar shape of the first sub-pixel, the planar shape of the second sub-pixel and the planar shape of the third sub-pixel are all circular, and a diameter of a circle corresponding to the first sub-pixel is larger than a diameter of a circle corresponding to the second sub-pixel, a diameter of a circle corresponding to the second sub-pixel is larger than a diameter of a circle corresponding to the third sub-pixel.

14. The pixel arrangement structure according to claim 1, wherein a quadrilateral formed by connecting geometric centers of two second sub-pixels and geometric centers of two third sub-pixels comprised in the second display unit is a parallelogram, and a geometric center of a first sub-pixel comprised in the second display unit coincides with an intersection point of two diagonals of the parallelogram;
in the second display unit, a fourth pitch is between the first sub-pixel and any one of the second sub-pixels, and a fifth pitch is between the second sub-pixel and the third sub-pixel adjacent to it, a sixth pitch is between the first sub-pixel and any one of the third sub-pixel, any two of the fourth pitch, the fifth pitch and the sixth pitch are not equal.

15. The pixel arrangement structure according to claim 1, wherein the first sub-pixel, the two second sub-pixels and the two third sub-pixels comprised in the second display unit are located in an irregular hexagon.

16. A display panel, comprising a display region and a non-display region, wherein the display region is provided with a plurality of pixel openings with the pixel arrangement structure according to claim 1.

17. A display device, comprising the display panel according to claim 16 and a driving circuit for providing a driving signal to the display panel.

18. The pixel arrangement structure according to claim 3, wherein a quadrilateral formed by connecting the geometric centers of the two second sub-pixels and the geometric centers of the two third sub-pixels comprised in the second display unit is a parallelogram, and the geometric center of the first sub-pixel comprised in the second display unit coincides with an intersection point of two diagonals of the parallelogram.

19. The pixel arrangement structure according to claim 2, wherein the first sub-pixel is a blue sub-pixel, the second sub-pixel is one of a red sub-pixel and a green sub-pixel, and the third sub-pixel is the other of the red sub-pixel and the green sub-pixel.

20. The pixel arrangement structure according to claim 2, wherein a plurality of pixel groups are arranged in an array in a first direction and a second direction, the first direction intersects with the second direction, and is not perpendicular to the second direction, and geometric centers of a plurality of second display units are arranged in an array in the first direction and the second direction.
